(19) United States
(12) Patent Application Publication
(10) Pub. No.: US 2002/0041196 A1
(43) Pub. Date: Apr. 11, 2002

(54) Delay locked loop

(76) Inventors: Paul Demone, Kanata (CA); Joerg Stender, Munich (DE); Jamal Benzreba, Nepean (CA); Bruce Millar, Stittsville (CA); Xiao Luo, Santa Clara (CA)

Correspondence Address: Thomas A. Ward, Esq., FLIESLER DUBB MEYER & LOVEJOY LLP, Fourth Floor, Four Embarcadero Center, San Francisco, CA, 94111-4156, US

(21) Appl. No.: 09/907,267

(22) Filed: Jul. 17, 2001

Related U.S. Application Data
(62) Division of application No. 09/503,560, filed on Feb. 11, 2000.
(60) Provisional application No. 60/119,897, filed on Feb. 12, 1999.

(51) Int. Cl. H03L 7/06

(52) U.S. Cl. 327/158; 327/277

(57) ABSTRACT

A delay locked loop based clocking circuit includes a lead delay line followed by a period delay line. The lead delay line receives an input clock signal and includes an analog delay control input. The period delay line has a plurality of taps and an analog delay control input, and is operated such that the N taps divide a single period of an input clock. A selected tap of the period delay line, sometimes called a “virtual zero-degree tap,” is fed back and phase-compared with the input clock signal to adjust the delay of the lead delay line.

### CROSS-REFERENCE TO PROVISIONAL APPLICATION

This Patent Application claims the benefit of Provisional Application No. 60/119,897, filed Feb. 12, 1999.

### BACKGROUND

1. Field of the Invention

This invention relates generally to delay locked loop circuits (DLLs) for use in high frequency, high bandwidth memory interface applications.

2. Cross Reference to Other Applications and Other References

The following patent applications are owned by the owner of the present application, and their disclosures are hereby incorporated by reference:

Ser. No. 09/132,158 [Attorney Docket No. SLDM10251] filed Aug. 10, 1998, invented by Gustavson et. al and entitled, MEMORY SYSTEM HAVING SYNCHRONOUS-LINK DRAM (SLDRAM) DEVICES AND CONTROLLER.

Ser. No. 60/055,368 (Provisional) filed Aug. 11, 1997, invented by Gustavson et al. and entitled, HIGH SPEED MEMORY INTERFACE (SYNCLINK).

The following technical article discussing the general operational features of SLDRAM Memory Interface is also incorporated by reference: SLDRAM: High Performance Open-standard Memory, Peter Gillingham and Bill Vogley, IEEE Micro, November/December, 1997 pp. 29-39.

### BACKGROUND OF THE INVENTION

The evolution of the dynamic random access memories used in computer systems has been driven by ever-increasing speed requirements mainly dictated by the microprocessor industry. Dynamic random access memories (DRAMs) have generally been the predominant memories used for computers due to their optimized storage capabilities. This large storage capability comes with the price of slower access time and the requirement for more complicated interaction between memories and microprocessors/microcontrollers than in the case of say static random access memories (SRAMs) or non-volatile memories.

In an attempt to address this speed deficiency, DRAM design has implemented various major improvements, all of which are well documented. Most recently, the transition from Fast Page Mode (FPM) DRAM to Extended Data Out (EDO) DRAMs and synchronous DRAMs (SDRAMs) has been predominant. Further speed increases have been achieved with double data rate (DDR) SDRAM, which synchronizes data transfers on both clock edges. With the introduction of synchronous memories, the issue of properly synchronizing read and write data with external and internal clock signals has received much attention and is continuing to drive design innovations.

Various methods have been employed in the past to achieve the desired data/clock synchronization. Analog phase locked loops (PLLs) consisting of a phase detector, a charge pump and a voltage controlled oscillator (VCO) have been employed in the past to synchronize data with an external clock. These systems suffer from a number of drawbacks in today's mainly digital memory design environment. Firstly, PLLs employ analog elements which typically consume substantially more power than digital elements due to their current requirements. Secondly, recent trends towards decreasing nominal power supplies for reducing power consumption in high density memory applications runs against the need for fairly high power supply values for the analog elements of PLLs. Thirdly, the length of time required to achieve a locked condition for PLLs is relatively large due to the need to drive the VCO to the correct frequency. In general, in digital systems such as memories, microprocessors and ASICs, these types of PLLs introduce unnecessary analog design complications in a mainly digital design and therefore have recently been avoided.

An alternate approach to clock data synchronization can be achieved through the use of a Delay Locked Loop (DLL) as described in U.S. Pat. No. 5,796,673 to Foss et. Al and U.S. Pat. No. 5,777,501 to Abouseido, both assigned to MOSAID Technologies Inc. and both incorporated herein by reference. Delay locked loops use a digitally adjustable delay line with numerous outputs for selecting the appropriate output clock signal to synchronize data with. Digital information is used to either include or exclude a certain number of delay elements within a delay chain. The ease of implementing DLLs in a digital system makes them the preferred solution in most digital applications.

Various other techniques have been used to address clock synchronization problems. For example, U.S. Pat. Nos. 5,311,483 to Takasugi and 4,754,164 to Flora et al, both incorporated herein by reference, illustrate digital delay lines utilizing a counter. A further example is U.S. Pat. No. 5,355,037 to Andersen et al, incorporated herein by reference, which discusses a high performance digital phase locked loop (DPLL) circuit consisting of a phase detector for detecting a phase difference between the external and internal clocks and a digitally programmable delay line for adjusting the delay. The very narrow lock window used in patent 5,355,037, incorporated herein by reference, makes the DPLL susceptible to losing its lock due to external jitter on the external clock. Also, the Andersen et al approach does not address the problem of wasted power arising from keeping unused portions of the delay line activated.

Techniques offering the implementation of either DLL or PLL circuits, ensuring synchronous operation over a wide range of frequencies by the use of a frequency or delay change-over circuit controlled by a mode select signal, have also been proposed; for example U.S. Pat. No. 5,754,838 to Shibata, incorporated herein by reference. Furthermore, a high bandwidth application DLL design employing a differential charge pump and a phase shifter is presented in U.S. Pat. No. 5,614,855 to Lee. et al., incorporated herein by reference. The use of the phase shifter allows for various implementations for the phase detector such as a data receiver or a quadrature phase detector. The duty cycle of the output clock is also controlled by duty cycle correction amplifiers. This approach, although fairly robust, is generally an analog solution, employing a number of complex analog elements such as the differential charge pump, the duty cycle correction amplifiers, and the phase mixer, and as a result, suffers from the same general drawbacks of implementing analog circuits in the digital domain as were mentioned above.

Given current high speed, high bandwidth design targets, a digital solution consuming less power while still achieving the high speed synchronization requirements is desirable.

### SUMMARY OF THE INVENTION

Roughly described, the invention includes the following aspects:

“Virtual 0° tap” scheme. An additional delay stage inserted between the clock receiver and the period delay line for compensating for drift caused by variations in voltage and temperature. The scheme decides, during the DLL locking sequence, which tap is closest to the required phase for the feedback loop and picks that tap as the 0° tap and maintains it during DLL operation.

Period Delay Line. A single delay line consisting of 32 differential delay stages adjusted to cover one clock period, with taps after each stage, for providing 32 phases of the clock.

Geometrically encoded DAC used for controlling the period line; also, skewing the IDAC transistor sizes to compensate for any non-linearity in the delay elements.

Phase Detectors described and illustrated herein for lead and period delay lines.

The DLL control circuitry ensures stability before and after lock over a wide frequency range. Loop start-up and initial phase match problems are completely eliminated through the use of a deterministic seeking technique. A phase decimation filter with self-generation of a phase indication error signal, along with an update clock, eliminate external clock jitter effects and significantly reduce the overall jitter of the system.

### BRIEF DESCRIPTION OF THE DRAWINGS

FIG. 1 is a block diagram of a prior art digital phase locked loop circuit.

FIG. 2 is a block diagram of a prior art digital delay locked loop circuit,

FIG. 3 is a block diagram of a prior art delay locked loop circuit.

FIG. 4 is a simplified functional block diagram of the general clocking scheme according to an embodiment of the present invention.

FIG. 5 is a simplified functional block diagram of a DLL circuit susceptible to drift due to voltage and temperature variations.

FIG. 6 is a simplified functional block diagram of a DLL circuit according to an embodiment of the present invention employing the “virtual 0° tap” scheme.

FIG. 7 is a detailed schematic diagram of the lead and period delay lines.

FIG. 8(a) is a detailed schematic diagram of delay stages for the lead and period delay lines.

FIG. 8(b) is a detailed schematic diagram of the output tap stage of the period delay line.

FIG. 9(a) is a detailed schematic diagram of the lead delay line phase detector.

FIG. 9(b) is a detailed schematic diagram of the period delay line phase detector.

FIG. 10 is a simplified block diagram of the DLL and the control block.

FIG. 11 is a state flow diagram for DLL control.

FIG. 12 is a current mode digital-to-analog converter.

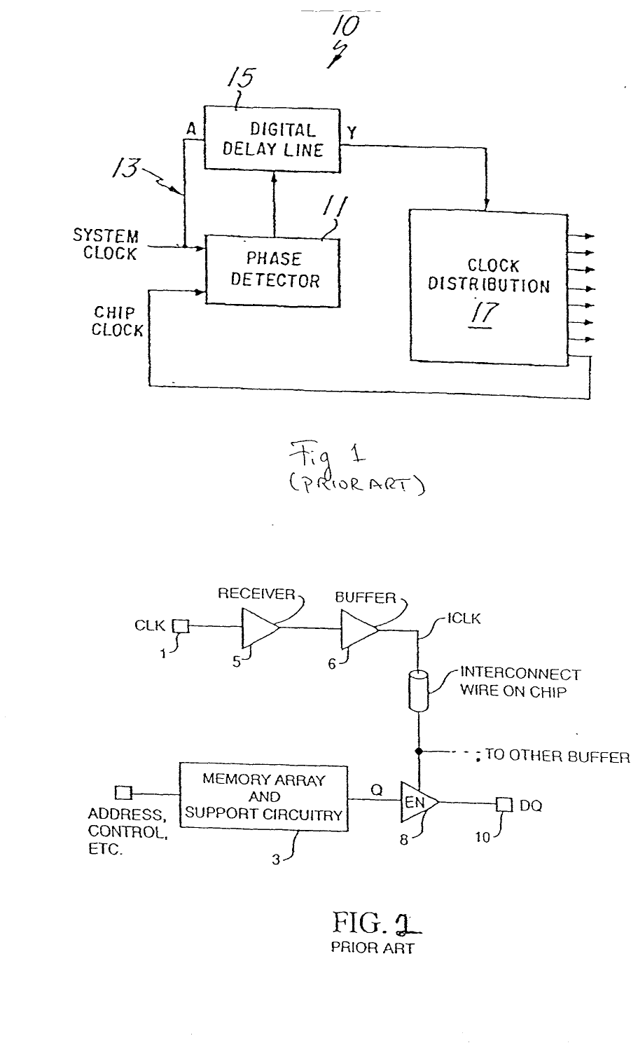

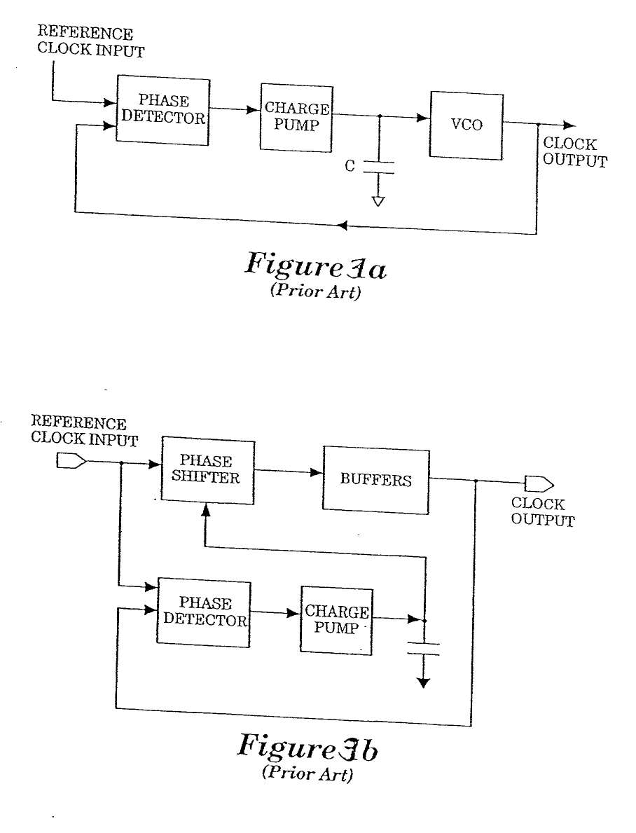

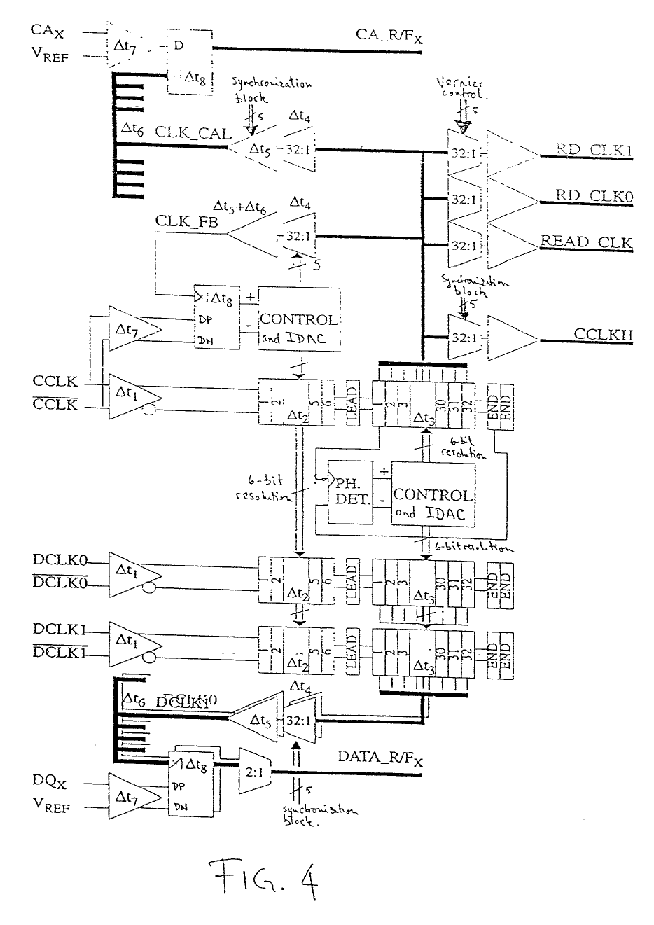

### DETAILED DESCRIPTION

General Discussion

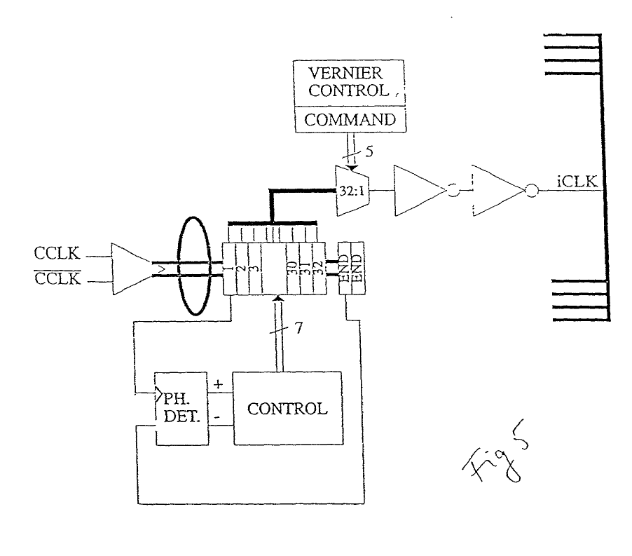

A simplified block diagram illustrating the clocking scheme employed in an integrated circuit employing an embodiment of the present invention is shown in FIG. 4. The clocking scheme makes use of three separate DLL lines, the main command clock delay line (receiving CCLK)and the two data clock delay lines (receiving the source-synchronous data clocks DCLK0, DCLK0/ and DCLK1, DCLK1/). All three delay lines are controlled by a main DLL control circuit and comprise a 32-stage delay portion referred to hereinafter as the period line, since its purpose is to divide the period into 32 equal steps, as will be described in further detail below, and a 6-stage lead delay portion.

The main loop comprises the period line and its control circuitry (which self-adjusts the period delay), and the lead line which compensates for any internal device drift. Six (6) separate clocks are provided as outputs from the main loop: CCLKH, READ_CLK, RD_CLK0, RD_CLK1, CLK_FB and CLK_CAL. CLK_FB feeds back to the lead delay line control circuitry an initially chosen “virtual 0° tap” (as will be described in further detail below). CLKH is the internal master clock, feeding all internal control circuitry and the DRAM core. The command input sampling clock (CLK_CAL), which is used to optimally sample a 15-bit pseudo-random synchronization sequence during initialization, usually shows the same setting as the main clock but is separated from the main clock in order to show a behavior similar to that of the critical data input clocks and also to improve load and line matching. The three remaining clocks provide output clocking READ_CLK) and the separate DCLK out fine adjustment (RD_CLK0, RD_CLK1).

The data clock (DCLK0,DCLK0/ and DCLK1,DCLK1/) delay lines are controlled by the same control block as the main line to achieve a similar delay. The outputs of the DCLK lines are connected to the obligatory [32:1] multiplexer and the DCLK driver which has the same behavior as the command input clock driver in order to ensure stable setup and hold windows. Since the data clocks are not free running clocks, they are unsuitable to derive any timing information. As a result, the timing of the data clock delay lines is completely mirrored from the main line.

During initialization, a single tap from the 32-stage delay line matching the CCLK is selected; this tap is hereinafter referred to as the “virtual 0° tap”. The 6-stage lead delay line compensates for delay in input buffers and clock distribution. On initialization, the control setting for the lead delay line is set to mid-range. During operation as temperature or voltage fluctuations occur, the lead delay line is adjusted to maintain the “virtual 0° tap” in phase with the external CCLK. To avoid jitter caused by jumping from one tap to another of the period delay line, the DLL is designed to maintain the same tap setting. The 32-stage period line is therefore phase-locked to one full period of the CCLK (in this case running at 200 MHz) and thereby remains constant phase relative to the external clock CCLK.

A number of the elements in FIG. 4 include an associated timing value with them denoted by Dt's. These values are used for simulation purposes to establish the loop path and measure the resolution. For example, the path from the CCLK, CCLK/buffer through the lead delay line, the period delay line, the [32:1] multiplexer, the CLK_FB driver and the D-type flip/flop, has a timing defined by Dt₁+(Dt₂)ᵢ+(Dt₃)ⱼ+Dt₄+Dt₅+Dt₆+Dt₈=T+Dt₇, where T is the period of CCLK, CCLK/and (Dt₂)_{I} is the tap position selected in the lead delay line and (Dt₃)ⱼ is the tap position selected in the period line. If the two sides of this timing equation are equal, then the feedback clock CLK_FB is in phase with the external CCLK. The timing values can be altered for simulation purposes to determine the effects of varying temperature and voltage.

DLL Lead Delay Line

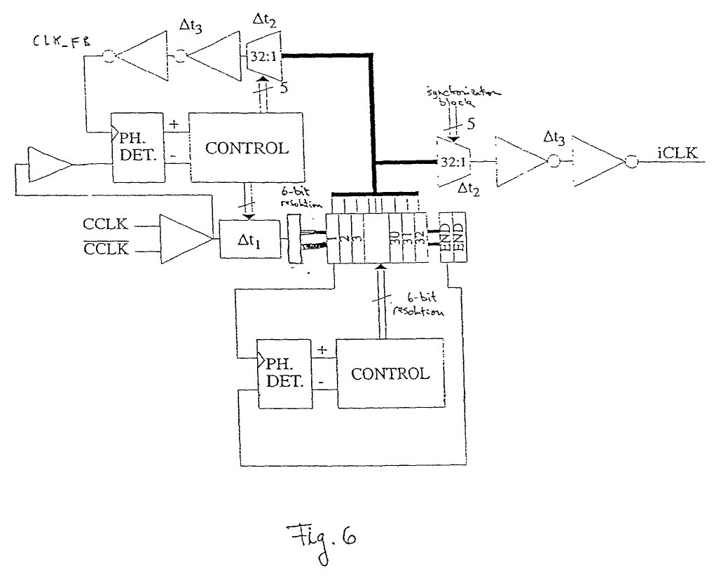

In order to illustrate the benefits of having a lead delay line, FIG. 5 illustrates a one-clock period delay line without the lead delay line. The main components of the period delay line include a clock receiver, the 32 delay elements, a [32:1] tap multiplexer, and a clock driver which feeds the clock distribution tree iCLK, as well as the phase detector and control circuitry for controlling the tap setting. The [32:1] multiplexer is controlled by a 5-bit register within vernier control circuitry, which can be selectively incremented, decremented, or reset to a median value by specific SLDRAM commands.

Since none of the above components are compensated for voltage or temperature variations in the input buffer, multiplexer or clock distribution (except for the delay line elements), a resulting significant voltage and temperature dependency arises for such a delay line implementation. Therefore, in order to achieve an overall drift compensation for the internal clock against voltage and temperature variations, a simple one-period delay line is insufficient. In the DLL shown in FIG. 5 for example, the range in delay from the external to an internal clock can vary between 4.76 ns to 5.54 ns over the specified voltage and temperature range.

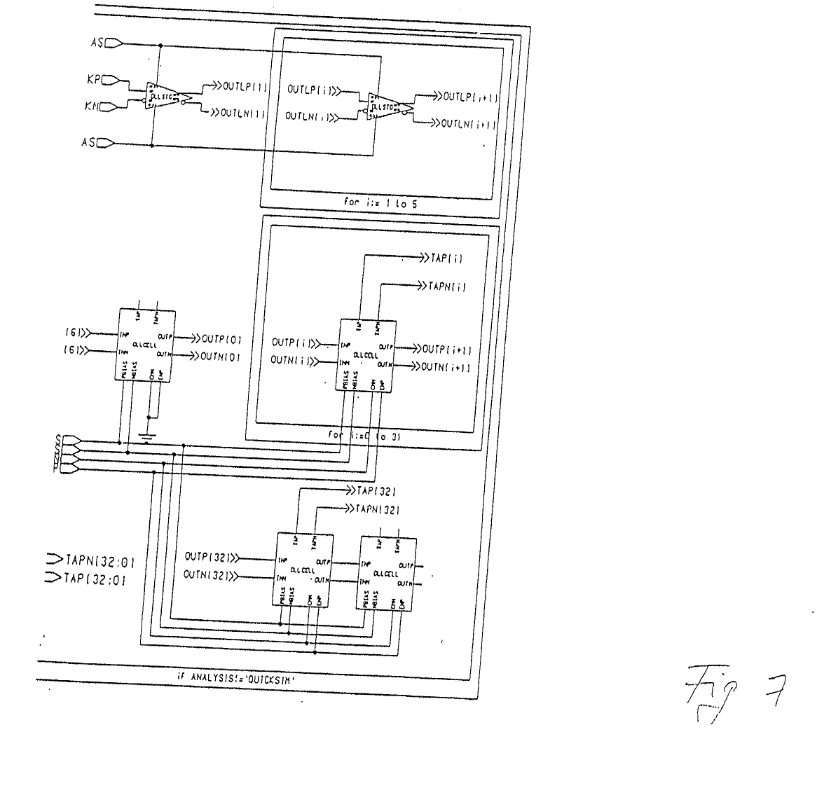

To address this variance, an additional lead delay line is introduced between the input clock receiver and the period delay line, as illustrated in FIG. 6. The lead delay line is adjustable to counteract the drift due to temperature and voltage and is responsive to a fed back version of a clock output from the period line, CLK_FB. In this case, a 6-stage lead delay line is shown with the delay elements being identical to those used in the main line, although other numbers of delay elements could be inserted, depending on the design specifications. The additional delay provided by the lead delay line is controlled according to a known reference, i.e. the CLK_FB clock via the [32:1] multiplexer, 2 buffers, a phase detector and control circuitry. The control circuitry, which will be described in further detail with respect to the DLL Control Block, produces a 5-bit output for selecting a tap position in the period delay line from the [32:1] multiplexer in the feedback path, as well as 2 analog signals for driving the lead delay line. The phase detector compares the buffered CCLK with CLK_FB and sends an increase or decrease signal to the control circuitry for selecting the 1-of-32 period delay line tap positions. This tap position remains fixed once the appropriate position has been selected. At the same time, the control circuitry increments or decrements the position of the delay setting in the lead delay line (recall that on initialization, the delay setting for the lead delay line was at mid-range) via the control value which changes based on the comparison made by the phase detector between the buffered CCLK and the fed back clock CLK_FB. As a result, the lead delay line is constantly self-adjusting itself, modeling all internal delays and compensating for voltage and temperature drift. Therefore, the representative output clock iCLK tracks CLK_FB which in turn tracks CCLK, eliminating voltage and temperature drift.

DLL Period Delay Line

The period delay line illustrated in FIG. 6 consists of 32 delay elements controlled by the DLL control block. A tap is taken off the first delay element and input into the phase detector, while the other input of the phase detector is taken from the 32^{nd} tap. This ensures that the tap(0) and the tap(32) positions have zero phase difference between them. The tap after the 32^{nd} tap is an additional tap position included for balanced loading of the last delay element.

Each of the 32 delay elements is controlled by a current digital-to-analog converter IDAC, as will be described in further detail in the DLL Control Block section below. The IDAC control allows the circuit to pick the tap “virtual 0° tap” position and remain on that position while the lead delay line compensates for voltage and temperature variations. In prior art approaches, once a DLL had locked to a tap position, the DLL would switch back and forth above and below the lock point. By using the IDAC approach to maintaining the locked point, there is far higher resolution than with jittering above and below the locked point.

Table 1 below illustrates the general operating functions of the two delay lines in the various operational states:

TABLE 1
DLL Operating States

| | Lead Delay | Period Delay Line | Period Delay Line |
|---|---|---|---|
| DLL State | Line IDAC | IDAC | Tap Setting |
| Initialization | mid-range setting | Adjust to input | Fixed on “virtual 0° |
| | | clock period | tap” position |
| Operation | Adjust to keep | Adjust to input | Fixed on “virtual 0° |
| | CLF FB = CCLK | clock period | tap” position |

The period delay line IDAC is adjusted through the feedback path taken by CLK_FB and the lead delay line, as well as through a feedback path within the DLL Control Block as will be described below. It is important to note that the period delay line does not switch delay stages once a locked condition has been attained for the first time during an active cycle. The “virtual 0° tap” position remains fixed as long as the device remains in synchronization, and the lead delay line is the one who is switching elements on-the-fly to compensate for voltage and temperature variations. However, that is not to say that the period delay line is rigid once locked condition has been reached. The current mode DAC in fact is constantly adjusting the operating current passing within the 32 delay elements to ensure that the overall delay is one CCLK period and this, each delay element accounts for exactly 1/32 of the CCLK period (i.e. T/32).

The 32-stage delay line which is phase-locked to one full period of the CCLK, therefore remains in constant phase relative to the external clock. Also, as a result of implementing the “virtual 0° tap” scheme, the required range of the lead delay, can be greatly reduced (in this case, it is implemented with only 6 delay stages).

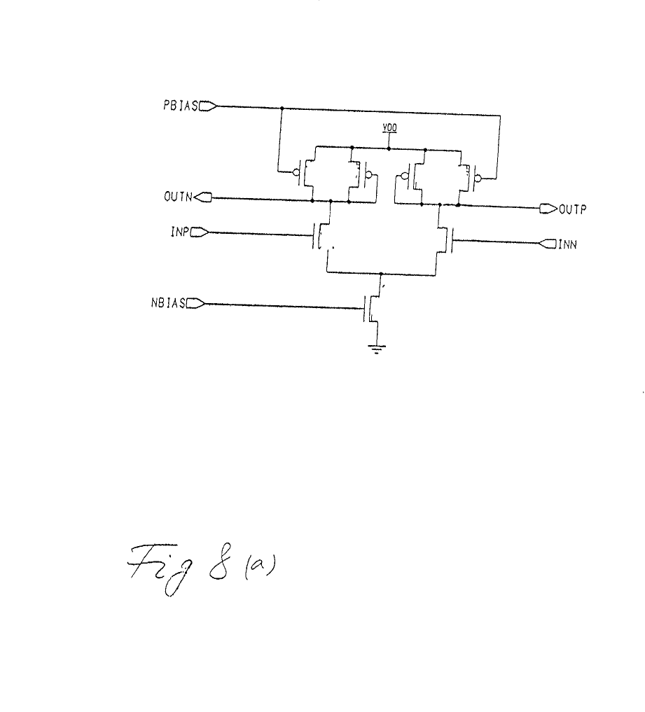

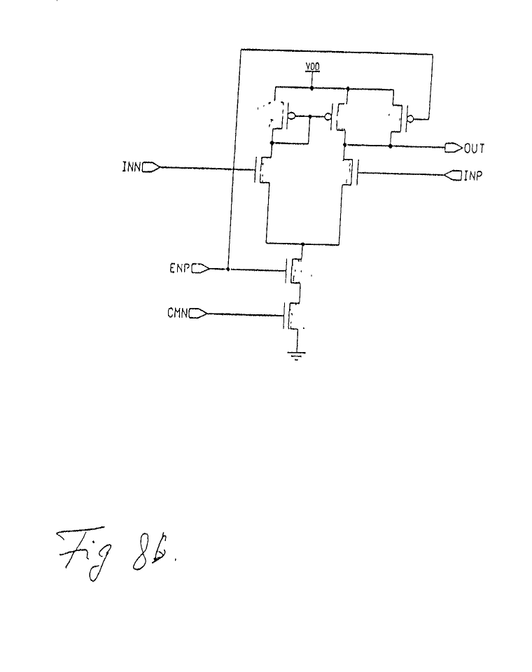

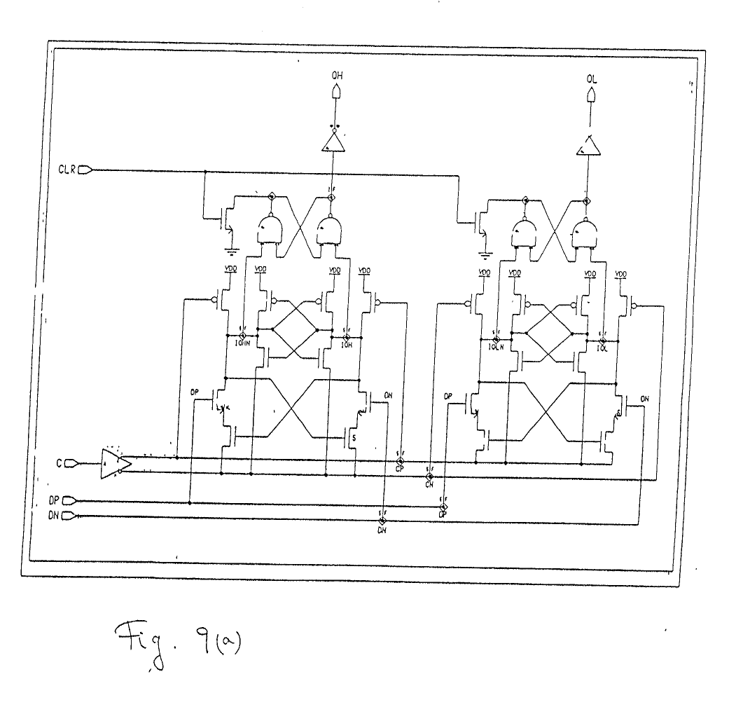

FIG. 7 is a hierarchical diagram showing detailed implementations of the lead and period delay lines and their interconnection according to an embodiment of the invention. The lead delay line comprises 6 differential DLL stages each controlled by a lead delay line PMOS transistor bias signal PLBIAS and a lead delay line NMOS transistor bias signal NLBIAS as illustrated in FIG. 8a. The delay stage shown in FIG. 8a is based on a circuit employed in an article in the Journal of Solid State Circuits, 11/96, authored by John Maneatis. The diode-connected PMOS transistors connected in parallel with the controlled PMOS devices, between the outputs and the power supply, form a controllable resistor in the PMOS branch of this modified current mirror-type amplifier. The controllable resistor approach exhibits more linearity than would single PMOS transistors connected between the output nodes and the power supply. The output of the final, 6^{th} delay stage in the lead delay line (OUTLP[6], OUTN[6]) is input into a sacrificial delay stage prior to being input into the first delay stage of the period delay line. This sacrificial delay stage coupling the two delay lines is included to provide proper signal behavior for the subsequent delay stage. Subsequently, the output from the sacrificial delay stage, OUTP[0], OUTN[0] is input into the first of 32 period delay stages. The period delay stages are the same as the delay stages used in the lead delay line, as illustrated in FIG. 8a, except also connected in parallel to each delay stage is a tap stage, as illustrated in FIG. 8b. Controlling each tap stage are two signals: enable ENP and current bias CMN. The tap stages are used to output 32 signals corresponding to 32 divisions of the CCLK.

Phase Detection

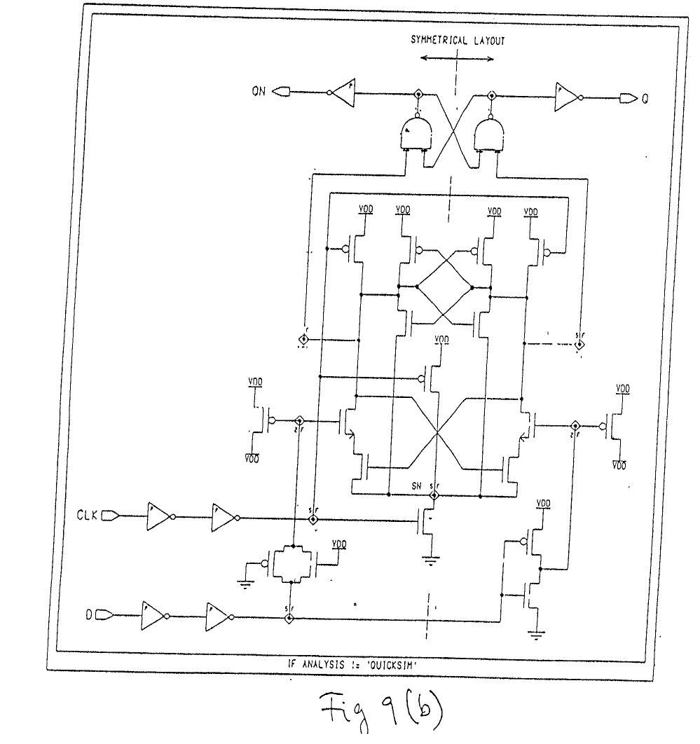

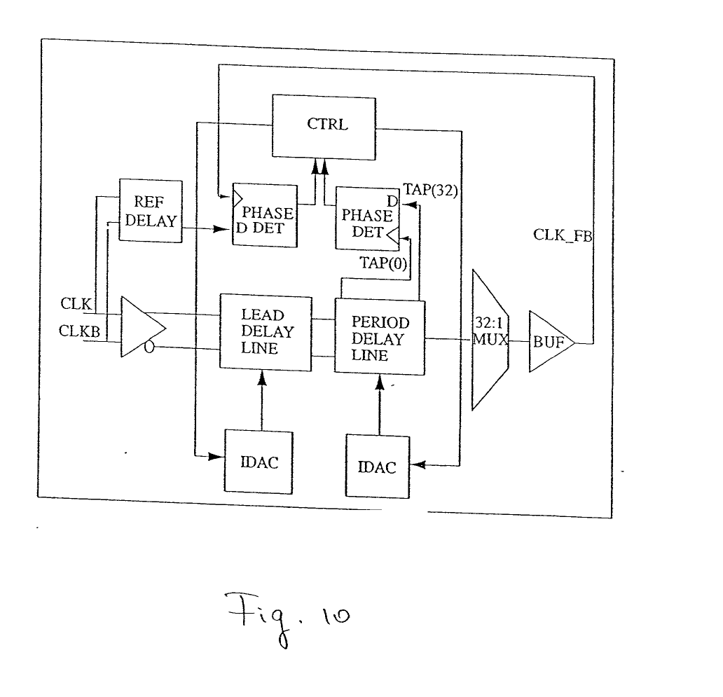

There are two phase detectors used in the DLL circuit, one for the period line and one for the lead delay line. The lead delay line phase detector shown in FIG. 9a is based on based on an improvement to a circuit disclosed in U.S. Pat. No. 5,497,115 assigned to MOSAID Technologies Incorporated and incorporated herein by reference. There are a few major differences between the two circuits: the circuit of FIG. 9a consists of two separate flip/flop circuits, one for providing the high output QH and the other for providing the low output QL. The generation of the two separate outputs allows for optimization for both rising and falling clock edges, whereas in the circuit of patent 5,497,115, the flip/flop would only operate on the rising clock edge. Although only the rising edge was used in this application, either the rising or the falling (not both) edges could be used, depending on the application. The phase detector as shown in FIG. 9a was selected for the lead delay line in order to mirror the temperature and voltage characteristics of the data input path (not that both the lead delay phase detector and the data input buffer have the same Dt₈ timing as shown in FIG. 4). Secondly, pull-down path of the capture latch has been simplified in the circuit of FIG. 9a by connecting the sources of the two pull-down transistors to one of the complementary outputs of the clock buffer. Thirdly, the drains of the NMOS transistors receiving the complementary data inputs have been cross-coupled to the gates of the NMOS pull-down transistors in the input paths. This cross-coupled connection assists in the sensing and latching of the complementary input signals in conjunction with the action of the capture latch. Finally, the holding latch is comprised of cross-coupled NAND gates, allowing for external control of the circuit through the clear signal CLR.

The period delay line phase detector shown in FIG. 9b is also based on an improvement to a circuit disclosed in U.S. Pat. No. 5,497,115. Functionally equivalent to a D-type flip/flop, the phase detector shown in FIG. 9b receives an input signal at its D-input and subsequently internally generates complementary input signals D_IN and DX_IN for inputting into a differential pair consisting of transistors 15 and 17. As discussed above with respect to the lead delay line phase detector, the NMOS cross-coupled pull-down transistors 16 and 18 ensure a narrow sensing window and assist in the sensing and latching of the complementary data inputs. The capture latch consisting of transistors 4, 5, 6, 7, can only hold data for one clock cycle, since it gets precharged on every falling edge of the input clock through PMOS transistors 1 and 3. Therefore, the cross-coupled NAND gates 8 and 10 are included as a holding latch to store the input beyond the first clock cycle. Since the clock resets the circuit on every cycle, there is a low probability of undetermined states. To ensure identical initial sensing conditions, the additional PMOS device 2 also resets node C on every clock cycle.

In prior art DLL designs, the delay introduced by a delay element was much larger than the delay carried by a delay stage in the preferred embodiment. As a result, a standard D-type flip/flop could be used as a phase detector in prior art DLL circuits, which had a set-up and hold time in the order of 100 ps. However, in an implementation such as one of the embodiments of the invention, since there are so many tap positions, each delay element is much shorter in duration. In order to effectively perform its function the phase detector in this application must therefore have a very small set-up and hold time i.e. smaller than a delay element in the period delay line (in this case, the set-up and hold time was 20 ps). The paths of D and CLK are therefore made equal through inverter paths 12, 13, dummy pass gate 14 and transistor 19, and transistors 20, 21. The narrow set-up and hold time ensures little operating variation with changes in voltage and temperature. The addition of the dummy pass gate 14 making D_IN equivalent in delay to DX_IN, and thereby ensuring that both rising and falling edges of incoming data are identical in setting the phase detector output.

DLL Control Block Circuitry

The DLL Control Block acquires and maintains phase match condition as well as reduces the susceptibility to jitter, while operating at data rates of 400-600 Mbps per pin, or approximately 200 MHz. Conventional DLL's used in SDRAMs typically operate at anywhere in the 150 MHz range. Schemes including fine and coarse delay lines with separate control circuits for each delay line as employed in conventional DLL circuits are still insufficient in providing the necessary operating parameters at the higher frequency range. According to an embodiment of the invention, the DLL control block employs a control scheme based on current-mode digital-to-analog converter (IDAC) technology for controlling the DLL, which allows much higher delay resolution and is less susceptible to jitter than conventional DLL control techniques. More specifically, the DLL control block employs a deterministic phase lock seeking scheme in conjunction with a phase decimation filter to eliminate external clock jitter and reduce the overall system jitter.

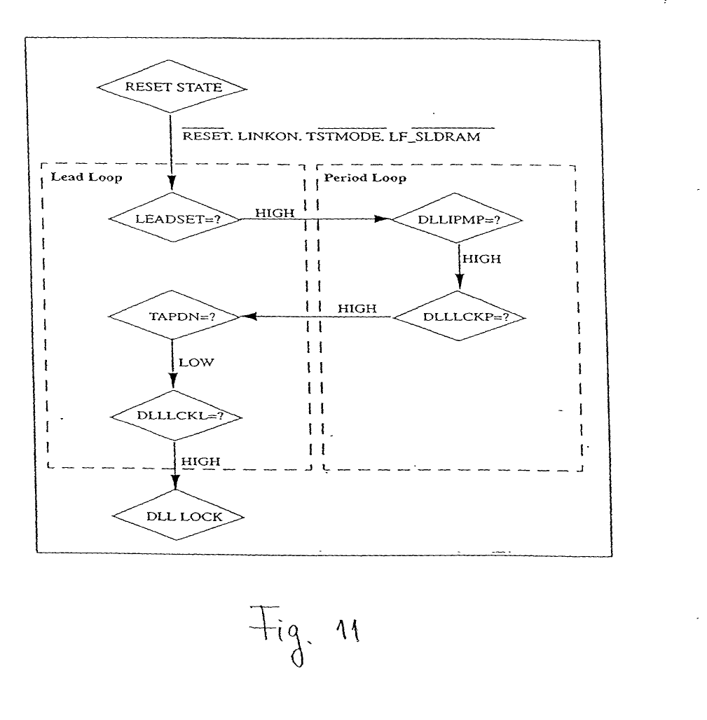

A simplified block diagram of the DLL feedback loop illustrating the use of the DLL control block is outlined in FIG. 10. The DLL control block is essentially a finite state machine (FSM) which is designed to ensure that the DLL tracks the rising edge of the external reference clock. The two delay lines are controlled by the two separate IDAC's, which in turn receive control signals from the control block circuitry. Although in this diagram the control block is shown as a single block, the block actually represents the combination of the control circuits for the period and the lead delay lines as illustrated in FIG. 4. As can be seen from FIG. 10, the lead delay line (CLK_FB) loop can be thought of as an outer loop or main loop, whereas the period delay line can be thought of as an inner loop.

A divide-by-4 clock is required to run the control logic prior to DLL lock in order to achieve fast initial phase match. In this application, the divide-by-4 clock was found to be the optimum minimum to allow the loop to settle.

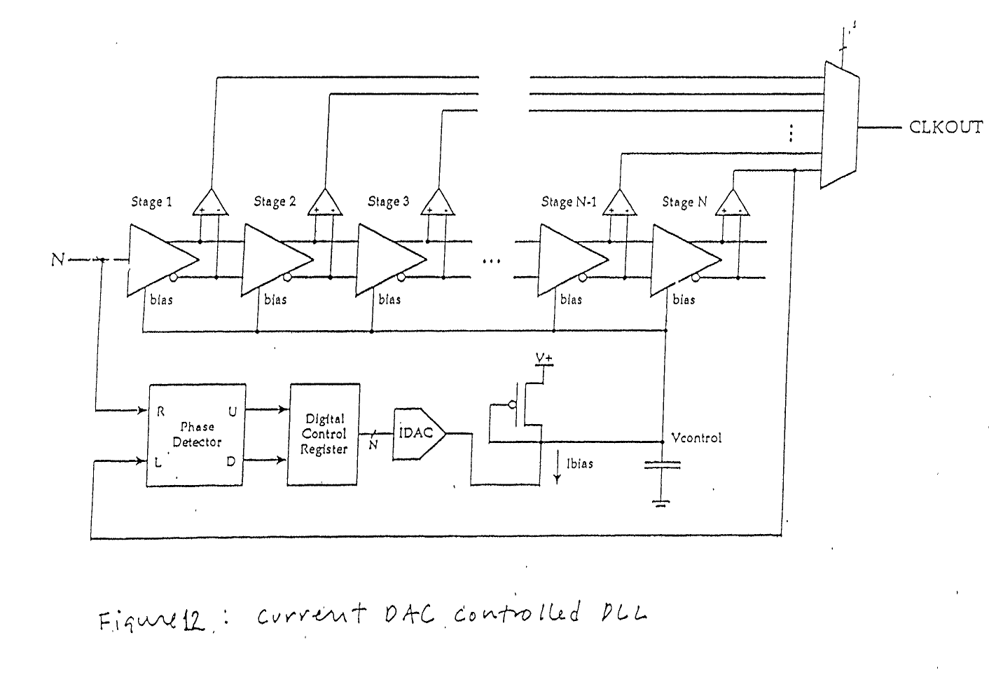

In terms of general operation with respect to FIGS. 10 and 11, immediately after RESET is de-asserted, if LINKON is active and TSTMODE and LF_SLDRAM are both low (signals associated with the device operation mode), the divide-by-4 clock generation starts and the lead delay line is initialized to the mid-range setting. When the lead stage delay is set (LEADSET:DSO is high), the period delay line loop starts and the initial phase match is sought. The phase pattern is made stringent enough to ensure that clock jitter does not cause false initial phase match. When the match condition is met, the initial phase match signal DLLIPMP goes high. Subsequently, the period phase loop filter is enabled to acquire lock for the period delay line. When the lock condition is established, DLLLCKP is high, the virtual zero tap is sought. Under the specified DLL operation, the virtual zero tap is guaranteed by design to lie in the first three quarters of the period delay line. After the virtual zero tap is found, TAPDN is low and the main phase loop filter is enabled to acquire lock for the main delay loop. Note that DLLLCKL may go high or stay low depending on how close the two loops are. In the worst case, when the two loops are very close, the DLL overshoots since the main loop compensates for the output delay error at the same time as the period loop.

Current-Mode Digital-to-Analog Converters (IDACs) The current DAC (IDAC) circuit illustrated in FIG. 12 is a current mode digital to analog converter. The IDAC consists of an 8 element row control shift register, an 8 element column control shift register, an array of 64 current sources and a bias generator. The DAC converts 1 of 64 digital settings to current and the bias generator converts the current to analog voltage and is geometrically scaled so that output current I(n)=Imn*S^{Λ}n where S is about 1.055. The purpose of this feature is to allow a single step up or down in the 6 bit digital control value that would change the overall delay in the DLL by about the same amount regardless of the absolute amount of current the DLL needs to lock to a given clock period (which varies with temperature, power supply voltage, and processing variation between individual chips). This property allows the entire DLL circuit to operate with a smaller maximum jitter and have amore controlled and reproducible timing resolution.

However, the propagation delay through an individual DLL delay element is not a perfectly linear function of the bias current set by the IDAC (typically the circuit saturates at higher current values so that each extra increment of bias current reduces the delay by a somewhat smaller amount). The general method of using a geometrically scaled DAC to control a DLL as described above, can be enhanced to correct for this effect. This modification involves changing the scaling of the 64 elements of the DAC to counteract the non-linearity of the delay vs. current transfer function of the DLL. In the case where the delay vs. current function slope smoothly falls off at high current, the DAC can be designed with a scaling factor that increases with higher current control settings.

Consider the general case where f is the transfer function of the DLL and g is the output function of a generalized DAC, then

Delay=f(I_{DAC}) where I_{DAC} is the DAC current

and I_{DAC}=g(N) where N is the DAC setting

A geometrically scaled relationship between Delay and N is desired, specifically:

Delay=Delay_min*S^{Λ}N=f(g(N))

Thus we can obtain this relationship if we design g(N) such that

g(N)=F(Delay_min*S^{Λ}N)

where F(x) is the inverse function of f(x), that is F(f(x))=x. Since the DAC current output for each of 64 settings is controlled by setting transistor ratios of the 64 individual current sources within the DAC we can implement an arbitrary function g(N) and thus correct for any characterized non-linearity in the DLL delay element.

Special scaling to counteract the non-linearity of the delay vs. current transfer function of the DLL is not required where the DLL delay element has a sufficiently linear transfer function so that a simple geometrically scaled encoding of the DAC is sufficient.

The foregoing description of preferred embodiments of the present invention has been provided for the purposes of illustration and description. It is not intended to be exhaustive or to limit the invention to the precise forms disclosed. Obviously, many modifications and variations will be apparent to practitioners skilled in this art. In particular, and without limitation, any and all variations described, suggested or incorporated by reference in the Background section of this patent application are specifically incorporated by reference into the description herein of embodiments of the invention. The embodiments described herein were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

1. Clocking apparatus comprising:
a first delay line coupled to receive an input clock signal, said first delay line having a sequence of at least one delay element and at least two taps; and
a second delay line coupled to receive a first delay line output signal from one of the taps of said first delay line, said second delay line having a sequence of at least one delay element and at least two taps.

2. Apparatus according to claim 1, further comprising a first delay control loop coupled to control the delay of said first delay line such that said first delay line output signal bears a predetermined phase relationship with said input clock signal.

3. Apparatus according to claim 2, wherein said predetermined phase relationship is a 0 degree phase relationship.

4. Apparatus according to claim 2, wherein at least a particular one of the delay elements in said first delay line includes a delay control input, and wherein said first delay control loop comprises:
a phase comparator having a first input coupled to receive said input clock signal and a second input coupled to receive a signal from a selected one of the taps of said second delay line; and
a control element coupled to control the delay of said particular delay element in response to said phase comparator.

5. Apparatus according to claim 2, further comprising a second delay control loop coupled to said second delay line to maintain the delay through said second delay line equal to one period of said input clock signal.

6. A clocking method comprising the steps of:
delaying an input clock signal through a first delay line such that an output signal of said first delay line bears a predetermined phase relationship with said input clock signal; and
phase-dividing said output signal of said first delay line to a plurality of taps of a second delay line.

7. A clocking method comprising the steps of:
delaying an input clock signal through a first delay locked loop, said first delay locked loop having an output signal;
phase-dividing said output signal of said first delay locked loop to a plurality of taps of a second delay line; and
controlling the delay of said first delay locked loop in response to a comparison between said input clock signal and a signal output from a particular one of the taps of said second delay line.

8. A method according to claim 7, further comprising the step of selecting said particular tap as the tap in dependence upon particular criteria.

9. Delay line apparatus comprising:
a delay line having a sequence of at least N delay stages, N>0;
at least two different tap outputs from said delay line; and
a delay controller coupled to control the delay of at least one of said delay stages in dependence upon the phase relationship between signals on said two tap outputs.

10. Apparatus according to claim 9, wherein a first one of said tap outputs is also an input to said delay line.

11. A delay line method comprising the steps of:
delaying an input clock signal through a delay fine having at least two taps; and
adjusting the delay of at least one delay stage of said delay line in dependence upon the phase relationship between signals on said two tap outputs.

12. A method according to claim 11, wherein one of said taps is also an input to said delay line.

13. DAC apparatus comprising a digital input port and an analog output port,
wherein the analog output port carries an analog signal having a value A(n)=A(0)*S^{Λ}n,
where n is the digital value on the digital input port, A(0) is the value of the analog output when n=0, and S is a constant.

14. Delay line apparatus comprising:
a delay element having a signal input, a signal output and a delay control input; and
a DAC having a digital input port and further having an analog output port coupled to said delay control input,
wherein the analog output port carries an analog signal having a value A(n)=F(Dmin*S^{Λ}n),
where n is the digital value on the digital input port, Dmin is a desired delay value of said delay element when n=0, S is a constant, and F(x) is the inverse function of the delay element transfer function.

15. A method for initializing clock circuitry, comprising the steps of:
providing an input clock signal to an input of a first delay circuit having a signal output and a delay control input;
providing the signal output of said first delay circuit to an input of a second delay circuit having a delay control input and further having N taps, N>1;
adjusting the delay of said second delay circuit until a first one of said taps bears a first predetermined phase relationship with a second one of said taps; and
adjusting the delay of said first delay circuit until a particular one of the taps of said second delay circuit bears a second predetermined phase relationship with said input clock signal.

16. A method according to claim 15, wherein said step of adjusting the delay of said second delay circuit precedes said step of adjusting the delay of said first delay circuit.

17. A method according to claim 15, further comprising the step of selecting said particular tap of said second delay circuit as a tap which most closely bears said second predetermined phase relationship with said input clock signal.

18. A method according to claim 17, wherein said steps of adjusting the delay of said second delay circuit, selecting said particular tap of said second delay circuit, and adjusting the delay of said first delay circuit, occur in sequence.

19. A method for initializing clock circuitry, comprising the steps of:
providing an input clock signal to an input of a first delay circuit having a signal output and a delay control input;
providing the signal output of said first delay circuit to an input of a second delay circuit having a delay control input and further having N taps, N>1;
adjusting the delay of said second delay circuit until a first one of said taps bears a first predetermined phase relationship with a second one of said taps; and
selecting as a particular tap of said second delay circuit, a tap which most closely bears a second predetermined phase relationship with said input clock signal.

20. A method for initializing clock circuitry, comprising the steps of:
providing an input clock signal to an input of a first delay circuit having a signal output and a delay control input;
providing the signal output of said first delay circuit to an input of a second delay circuit having a delay control input and further having N taps, N>1;
selecting as a particular tap of said second delay circuit, a tap which most closely bears a predetermined phase relationship with said input clock signal; and
adjusting the delay of said first delay circuit until said particular tap bears said predetermined phase relationship with said input clock signal.

21. A method for initializing clock circuitry, comprising the steps of:
providing an input clock signal to an input of a first delay circuit having a signal output and a delay control input;
providing the signal output of said first delay circuit to an input of a second delay circuit having a delay control input and further having N taps, N>1; and
adjusting the delay of said first delay circuit until a particular one of the taps of said second delay circuit bears a second predetermined phase relationship with said input clock signal.
